(19) United States
(12) Patent Application Publication
(10) Pub. No.: US 2007/0108435 A1
(43) Pub. Date: May 17, 2007

(54) Method of making nanowires

(76) Inventors: Eric S. Harmon, Norfolk, MA (US); Jerry M. Woodall, West Point, IN (US); David B. Salzman, Chevy Chase, MD (US)

Correspondence Address: Dave Garrod, Ph.D., Esq.;Goodwin-Procter, 599 Lexington Avenue, New York, NY, 10022, US

(21) Appl. No.: 11/349,458

(22) Filed: Feb. 7, 2006

Related U.S. Application Data
(60) Provisional application No. 60/650,837, filed on Feb. 7, 2005.

(51) Int. Cl. H01L 29/06

(52) U.S. Cl. 257/9

(57) ABSTRACT

A novel technique for manufacturing nanostructures and nanostructure is disclosed. The invention exploits techniques to deposit a second semiconductor material on a first semiconductor material with incomplete coverage of the second layer, and forming the nanostructures by filling the holes in the second semiconductor layer with a third semiconductor material. This allows the production of nanowires, nanorods, nanocylinders, and nanotubes with a controllable density and size distribution. Additionally, contact can be made to the bottom of the nanostructures through the first semiconductor layer allowing large area contacts to arrays of nanostructures to be formed. Similarly, contact can be made to the top of the nanostructure by direct deposition of a large area contacting layer. This allows the formation of nanostructure diodes and other nanostructure interconnections. Furthermore, a third large area contact to the second semiconductor layer can be used to modulate the conductivity of the arrays of nanostructures, enabling realization of a wide variety of nano transistors.

### FIELD OF THE INVENTION

This invention relates generally to the field of creating nanoscale materials and nanoscale devices, and more particularly to the design and fabrication of semiconductor nanocylinders, nanorods, nanotubes and nanowires oriented in a semiconductor matrix. It applies especially to transistor devices, memory cells, chemical sensors, photodetectors, diodes, and other devices built from these semiconductor nanoscale materials.

### BACKGROUND OF THE INVENTION AND LIMITATIONS OF THE PRIOR ART

It is well-known that important physical and chemical properties of semiconductors can differ markedly between traditional size scales and the nanoscale. Several notable benefits of semiconductor nanostructures include the following:

1. Quantum confinement: Quantum confinement from the interface between the nanostructure and the surrounding material can be used to shift the band gap, confine charge carriers, and exaggerate electronic properties. Quantum confinement can also be used to restrict the free carrier density of states in one, two, or three dimensions.

2. Nanoelectronic devices: Aggressive scaling of semiconductor devices typically relies on complex, expensive scaling of optical lithography to deep sub-um dimensions. The inherently deep sub-um dimensions of nanoscale devices allows them to be placed inexpensively using large feature size (>1 μm) lithography without forfeiting the speed and performance advantage of their small active regions.

3. Materials limitations: Many of the techniques for assembling nanostructures together and with other materials allow broader choices among candidate semiconductors than approaches employing lithographic featuring, since the nanostructures can avoid the need to lattice-match the semiconductor to a crystalline substrate.

Consequently, microelectronic devices using nanocylinders, nanorods, nanotubes and nanowires have found use as active device components for transistors, memory devices, and conduction-based chemical sensors.

Nevertheless, making good, low-resistance, ohmic contacts and well-defined interface to nanocylinders, nanorods, nanotubes and nanowires remains problematic. It is also difficult to manipulate nanostructures for optimal placement within devices. For example, heroic nanowire experiments indicate good transistor performance, but real-world alignment of multiple nanowires together to form usable circuits from nanowires devices has proven impractical.

We disclose herein a new method of making nanoscale features that enables oriented nanocylinders, nanorods, nanotubes and nanowires to be fabricated inside a semiconductor matrix. The method greatly simplifies the step(s). of interconnecting nanoscale features and electrical contacts, and is robust, low-cost and reliable.

### OBJECTS OF THE INVENTION

Objects of the invention include a plurality of means for forming a plurality of nanostructures in a semiconductor matrix and the ensemble thus formed. Other objects of the invention include a plurality of means for forming p-type or n-type electrical contacts to bottom and top ends of nanostructures and to the semiconductor matrix, and the systems thus formed. Other objects include means for forming nanocylinders, nanorods, nanotubes and nanowires hollow versions of these, radially or axially varied versions of these, and nanodots, and the structures and systems thus formed. Another object of the invention includes a means for building devices from these nanostructures, such as field-effect transistors where the conductivity of the nanostructure is modulated via the field effect, bipolar transistors where the conductivity of the nanostructure is modulated via injection of minority carriers into the nanostructure, hot-electron transistors that take advantage of the nanoscale to achieve ballistic or nearly ballistic transport, unipolar hot-electron transistors, photodetectors, chemical sensors, diodes, and other electronic devices that can be built from combinations of diode junctions, field effect junctions, heterojunctions including isotype heterojunctions, and ohmic contacts.

### BRIEF DESCRIPTION OF THE DRAWINGS

FIG. 1A depicts a cross-section of the preferred embodiment of the invention, incorporating a lower first semiconductor layer, a second semiconductor layer with incomplete coverage, and a third semiconductor layer that fills in the holes in the second semiconductor layer to form the nanostructures within the plane of the second layer. Note that the term “layer” refers to a region of semiconductor material: a concept always captured by the broader, less specific term “semiconductor material.”

FIG. 1B depicts a top view of the preferred embodiment.

FIG. 2A shows a cut-away of a partial implementation of the invention, which includes only the first semiconductor layer and the second semiconductor layer with incomplete coverage.

FIG. 2B shows an atomic force microscope (AFM) image of the partial implementation of the invention, showing the nanoholes in the second layer.

FIG. 3A shows a cross section of an experimental realization with the layer structure shown in FIG. 2A.

FIG. 3B shows an AFM image of the layer of the experimental realization with the layer structure shown in FIG. 3A.

FIG. 3C shows the cross section of a test structure formed in the experimental realization with the layer structure shown in FIG. 3A.

FIG. 3D shows a top view microscope image of the experimental realization of the test structure of FIG. 3C.

FIG. 3E show the current-versus-voltage characteristics of the test structure of FIG. 3C.

FIG. 3F shows the current-versus-voltage characteristics of the test structure of FIG. 3C at low bias as a function of the top mesa diameter.

FIG. 3G shows the current density as a function of voltage characteristics of the test structure of FIG. 3C at low bias.

FIG. 4A shows the layer structure of a nanocylinder with multiple layers forming a radial compositional variation and a vertical compositional variation in accordance with the invention.

FIG. 4B shows another layer structure of a nanocylinder with multiple layers forming a predominately radial compositional variation of the nanocylinder in accordance with the invention.

FIG. 5 shows the layer structure capable of forming nanodots in accordance with the invention.

FIG. 6A shows the layer structure of a nanowire heterojunction bipolar transistor (HBT) in accordance with the invention.

FIG. 6B shows a cross section of a nanowire heterojunction bipolar transistor (HBT) fabricated from the layer structure of FIG. 6A.

### BRIEF SUMMARY OF THE INVENTION

A first semiconductor layer is formed from a first semiconductor material, upon which is deposited a second layer of a second semiconductor material. The growth conditions under which the second layer is deposited, and optionally annealed and/or further processed, are suited to provide incomplete coverage of the underlying first layer by the second layer, resulting in an array of holes in the second layer reminiscent of Swiss cheese, with at least 1% of said holes exposing all the way to the underlying first layer. A key aspect of the invention is that the density, diameter, shape, depth of the holes in the second layer, as well as the variation and distribution of these, can be controlled by the selection of the first and second semiconductor materials, and deposition and anneal conditions of both layers. Note that the invention's method of growing a porous (non-uniform, incompletely covering) second layer is not anticipated by prior art methods, which subtractively form holes in a uniform second layer, such as deep-reactive ion etching (DRIE), nucleopores, and acid-etching (decoration) along cracks. A third layer of a third semiconductor material is then deposited on the second layer. Nanorods, nanowires, and/or nanocylinders are formed from the third semiconductor material within the holes left vacant in the second semiconductor layer, surrounded by the second semiconductor material on the sides, and by the first semiconductor material below.

Subsequent steps may be useful for further completing devices. Such steps may include, among others, adding metal, additional semiconductor materials, or adding dielectric materials; removing some of the third layer by polishing, etching, or other processing; removing some of the additional semiconductor materials by polishing, etching, or other processing; isolating a first plurality of such nanostructures from a neighboring second plurality; or other functions.

### DETAILED DESCRIPTION OF THE FIGURES

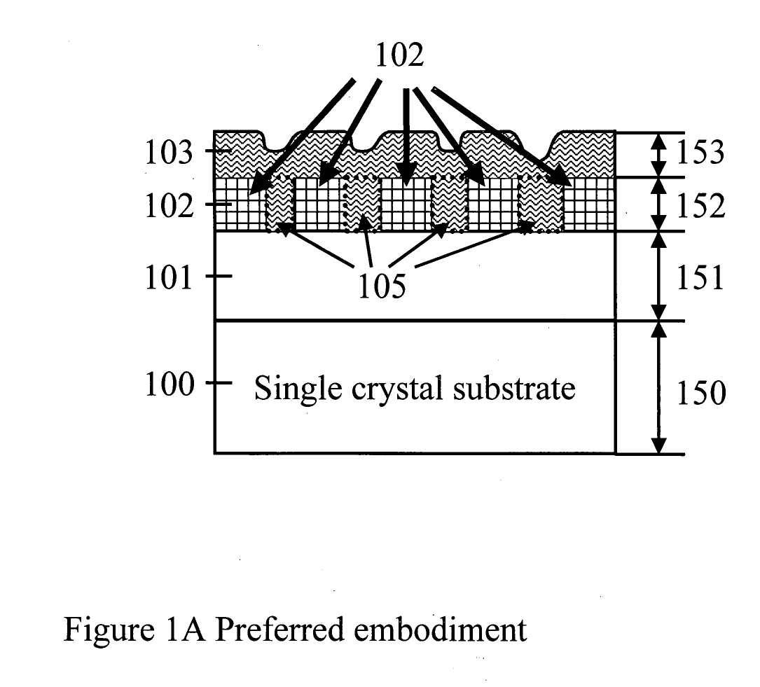

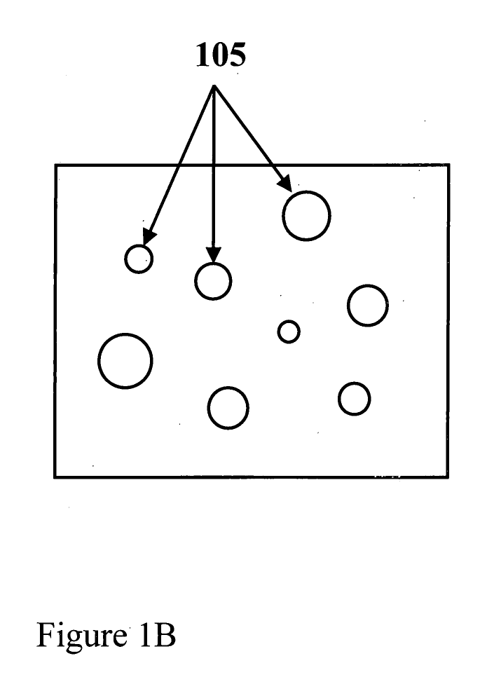

Reference is now made to FIGS. 1, showing the preferred embodiment of the invention, including the first, second, and third layers of first, second and third semiconductor materials respectively. The first layer 101 acts as a substrate and provides a means for contacting. the bottom end of the nanostructures. It will advantageously have high conductivity, and is preferably comprised of a single crystal of semiconductor material, though other materials are acceptable, such as a semimetal or a metal. The second layer 102 is grown on the first layer, and forms an incomplete coverage such that a plurality of holes exist throughout the second layer 102, exposing the top of layer 1 in at least 1% of the holes.

In the preferred embodiment, the second layer 102 of semiconductor is deposited on the first semiconductor layer using molecular beam epitaxy (MBE) with growth conditions optimized to provide incomplete coverage such that the second semiconductor layer contains a controllable density and size distribution of holes 105. Subsequent deposition of a third semiconductor layer 103 fills the holes 105 with the material comprising the third semiconductor layer 103, thereby forming nanostructures of the third material 103 in the holes 105 of the second material 102. In the preferred embodiment, at least 1% of the holes 105 go all the way through the second layer 102 so that the third semiconductor layer 103 makes intimate contact with the first semiconductor layer 101, allowing ohmic contacts to the bottom of the nanostructures to be formed through the first semiconductor layer 101, and ohmic contact to the top of the nanocylinders to be formed via a large area contact to the third semiconductor layer 103. Contact may also be made to the second semiconductor material 102, which can be used to provide a means of modulating the conductivity of the nanostructures directly, enabling a variety of transistor structures to be built. In certain alternative embodiments, 0.1%, 0.5%, 2%, 3%, 4%, 5%, 6%, 8%, 10%, 20%, 30%, and 50% of the holes 105 go all the way through the second layer 102 so that the third semiconductor layer 103 makes intimate contact with the first semiconductor layer 101.

In alternative embodiments, these contacts can be a Schottky contact, a tunneling contact (e.g. through a thin layer of a fourth semiconductor material with a wide band gap and large band offsets to the first and third semiconductor layers), or a non-conducting field-effect contact (e.g. through a thick layer of a fourth semiconductor material).

Reference is now made to FIG. 1A showing a side view of the preferred embodiment of the invention. On top of single-crystal substrate 100 of thickness 150 is grown a first semiconductor layer 101 to a thickness 151. In general, the lattice constant of layer 101 does not need to be matched to the lattice constant of substrate 100, so long as suitable pseudomorphic growth conditions are employed to ensure that layer 101 exhibits a suitably smooth surface. In some alternative embodiments, it may not be necessary to keep the surface smooth, provided that the overlying semiconductor layer 102 exhibits a suitable distribution holes for the formation of nanostructures. On top of layer 101 is grown a second semiconductor layer 102 of thickness 152. Growth conditions of layer 102 and thickness 152 are chosen such that incomplete coverage is achieved, resulting in the formation of holes 105. The size, geometry, and density of. the holes are dependent on growth conditions. After completion of the deposition of the second semiconductor layer 102, layer 103 is grown to a thickness 153 using growth conditions optimized to fill holes 105 as shown in the diagram. The filled holes 105 form the nanostructures in accordance with the invention. In certain alternative embodiments, the holes 105 are incompletely filled so that nanostructures can be hollow or filled with further layers of material deposited or plated by standard semiconductor processes.

When the first semiconductor layer 101 and third semiconductor layer 103 use closely related semiconductor compounds, and the second semiconductor layer 102 uses a different semiconductor material, the nanostructure acts as a nanowire connecting the first and third layers. The process supports easy formation of good ohmic contacts to the nanowire, because contacts can be made to the first semiconductor layer 101 and third semiconductor layer 103 with coarse (lateral) tolerances, and do not need to be made directly to the wire itself with tolerance to a deep sub-μm scale. The conductivity of the nanowire can be modulated by adding a third contact to the second semiconductor material 102, and using this contact to modulate the conductivity of the nanowire via the field effect or through injection of minority or majority carriers into the nanowire.

Reference is now made to FIG. 1B showing a top view of the holes 105. In general, the sizes of the holes 105 and the spatial distribution will depend on growth parameters, and need not be uniform.

It should be noted that the invention extends naturally to forming other nanostructures and pluralities of nanostructures, including nanowires, nanorods, nanocylinders, hollow nanocylinders, and nanodots. Hollow nanocylinders are formed where the second semiconductor layer preferentially adheres to the walls of the hole, and not to the first layer. Such hollow nanostructures allow an additional variation of the radial structure of the nanocylinder, where subsequent additional layers are deposited, causing a radial variation in the structure of the nanocylinder.

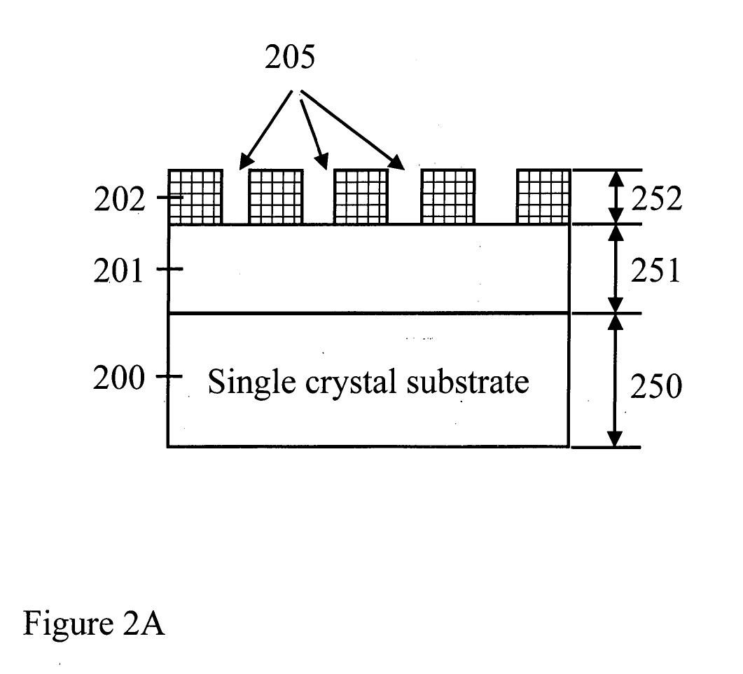

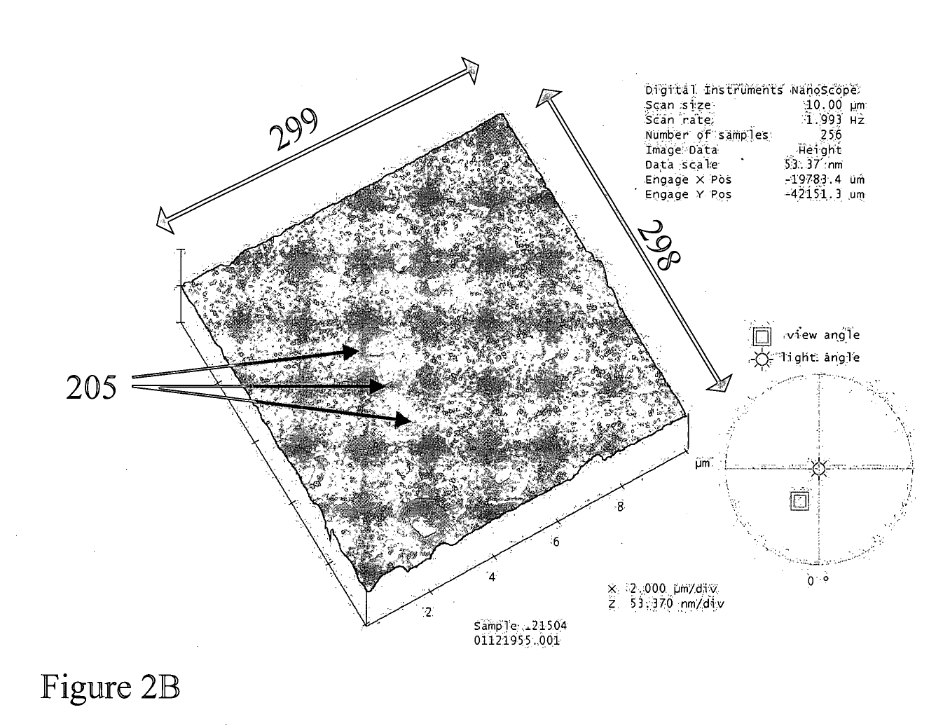

Reference is now made to FIG. 2A, showing the layer structure of a partial experimental realization of the invention with semiconductors layers 201 and 202 deposited using molecular beam epitaxy (MBE). On top of a GaP substrate 200 of thickness 250 is grown the first semiconductor layer 201 consisting of InAs grown to a thickness 251 of 1 μm. Layer 201 is grown using limited reaction epitaxial regrowth (LRER—see PCT/US05/07262), which produces smooth, single-crystal growth of InAs on GaP despite the 11% lattice mismatch. On top of layer 201 is deposited a GaAs layer 202 deposited to an average deposition thickness 252 of 20 nm. Layer 202 is grown at a substrate temperature of 500 C. Note that the lattice constant of GaAs layer 202 is about 7% smaller than the lattice constant of the underlying InAs layer 201. The compressive strain in the system and the growth parameters used result in the desired distribution of holes 205 in the GaAs layer 202, providing the basis for the nanostructure technology of the invention.

Reference is now made to FIG. 2B, showing an AFM image of the surface of the wafer grown with the layer structure described in FIG. 2A. The X dimension 299 is 10 μm and the Y dimension 298 is 10 μm. This AFM images reveal holes 205 at an average density of about 10⁷ cm⁻² in the GaAs second layer, with the average hole diameter being about 200 nm. Specific AFM measurements on selected holes reveal a hole with a 507 nm in diameter with a depth of 11.5 nm (which is only about half-way through layer 202) and a hole with a 351 nm diameter that is 21 nm deep (which is sufficient to provide intimate contact to the underlying InAs layer 201. FIG. 2B illustrates that these growth conditions are sufficient to create the desired density of holes 205 in GaAs layer 202.

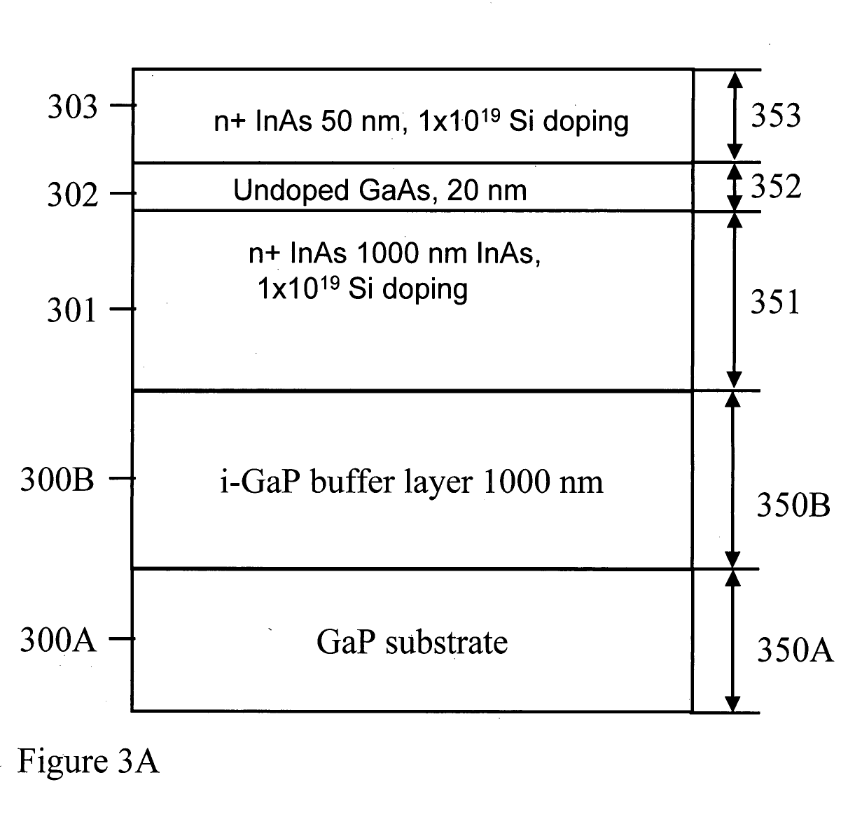

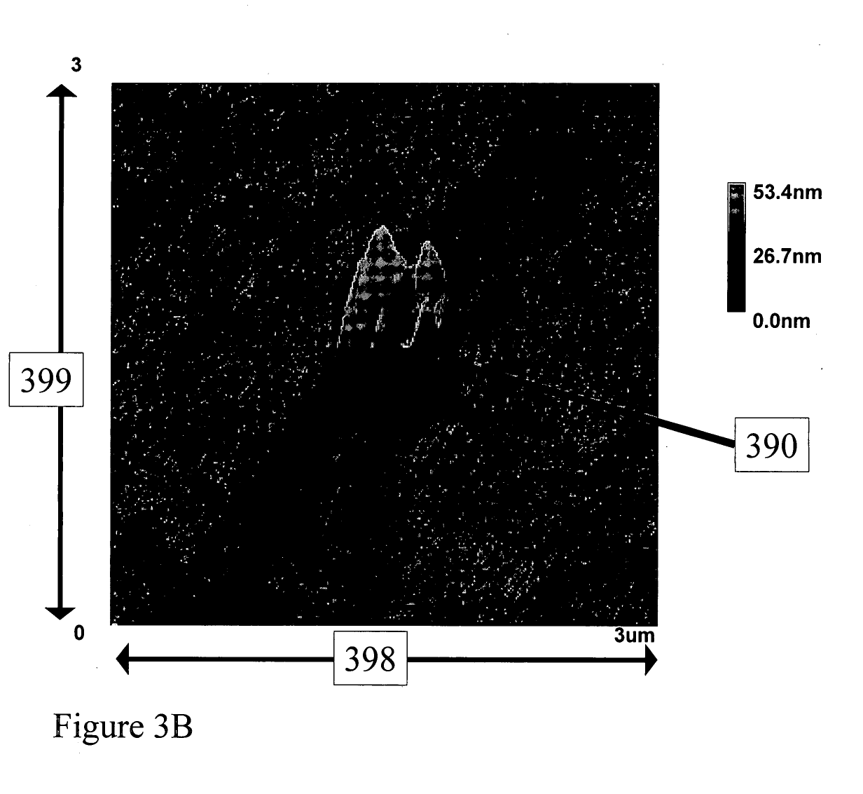

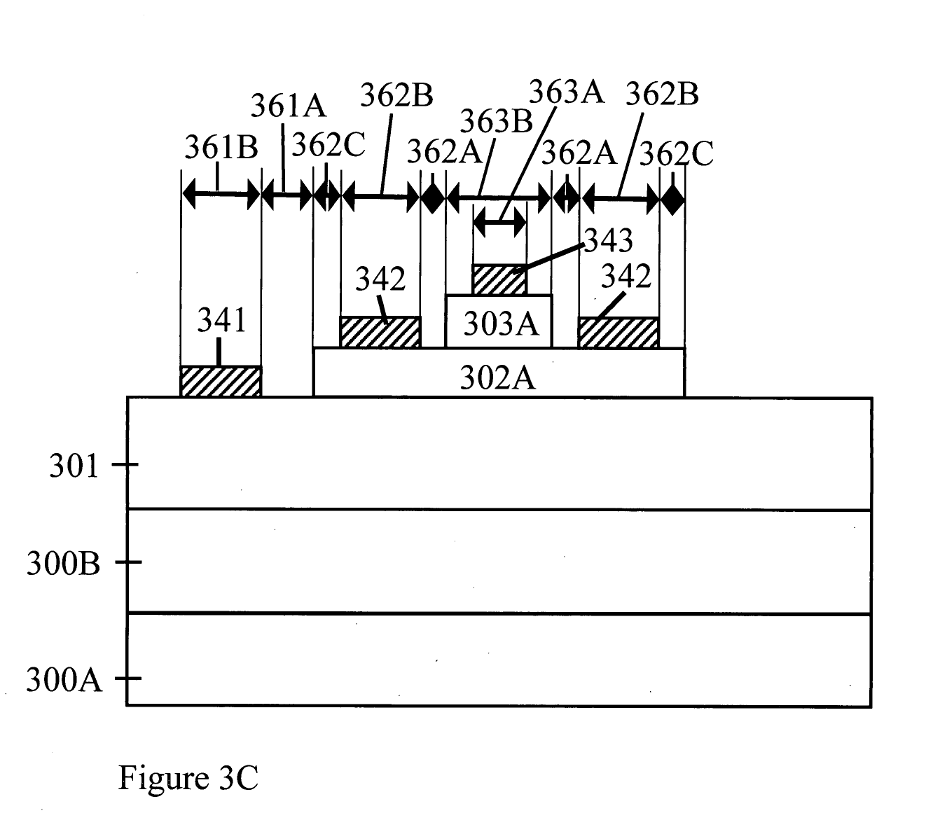

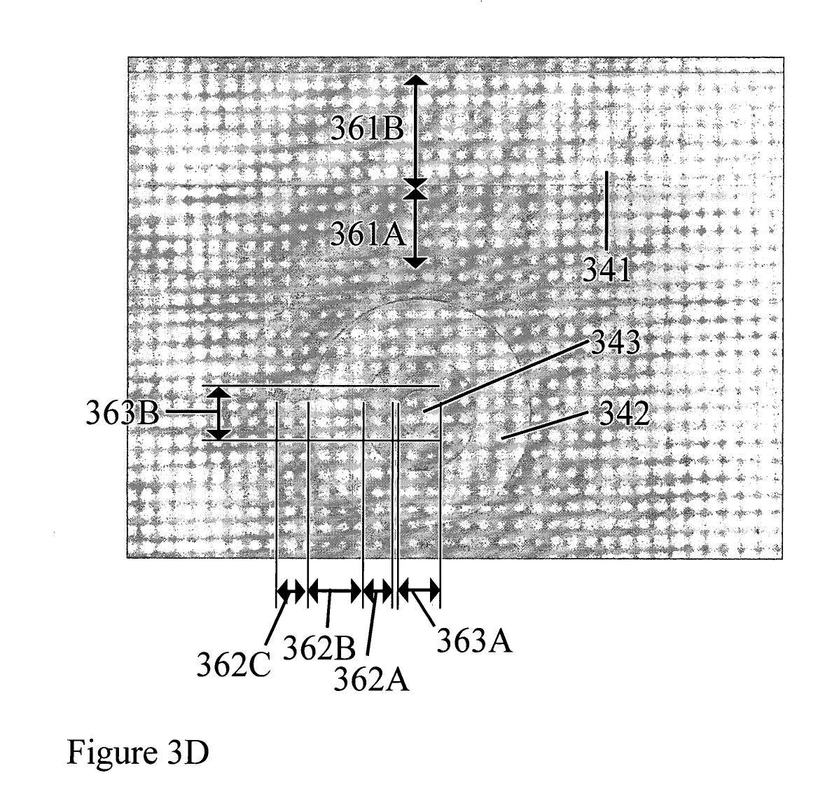

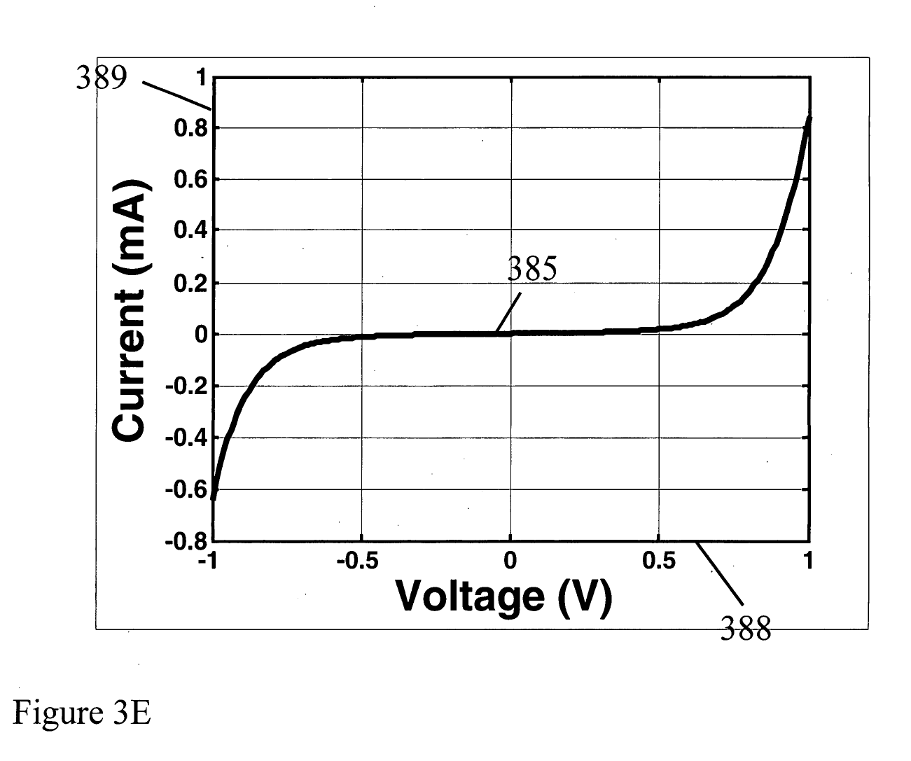

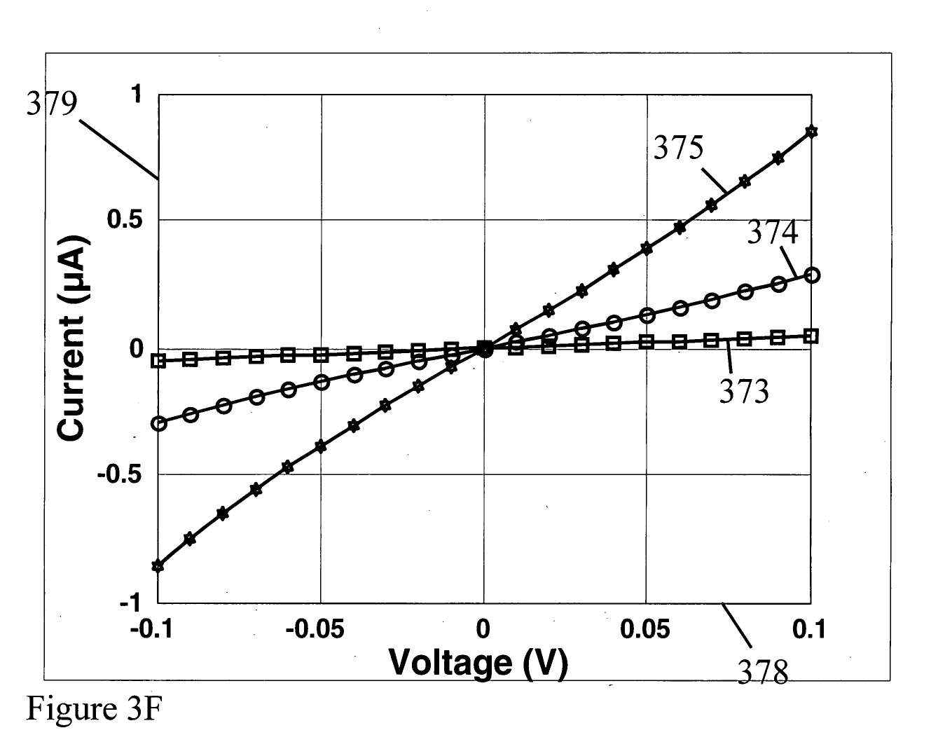

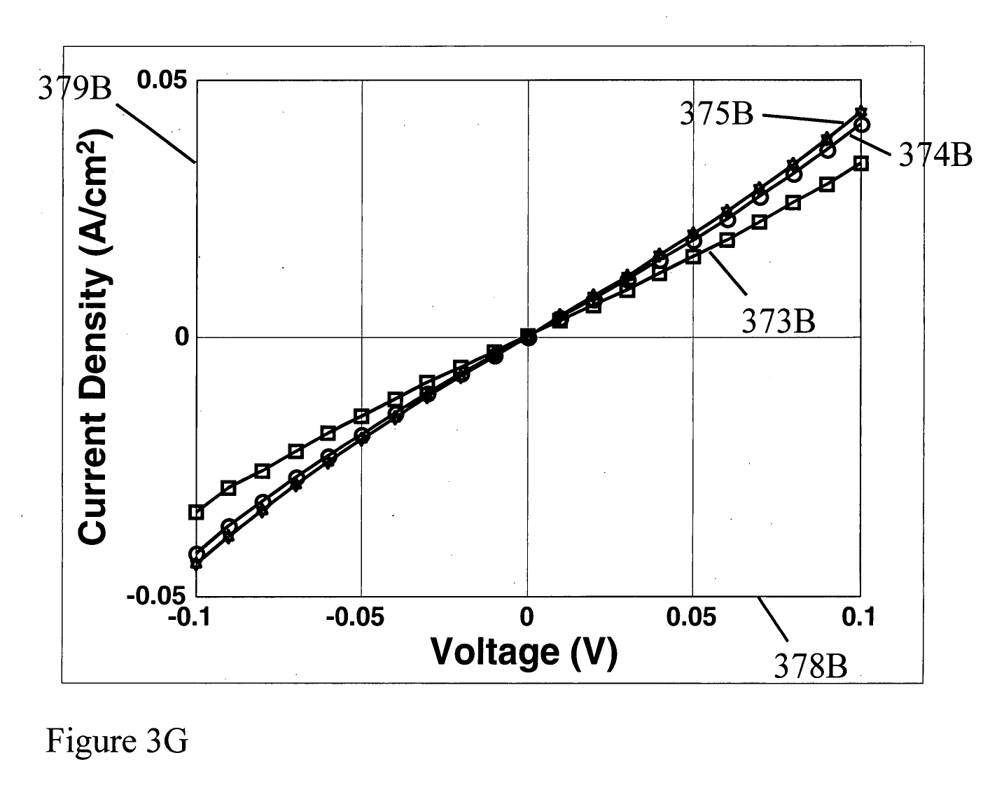

Reference is now made to FIG. 3A showing the layer structure of a complete experimental reduction-to-practice of the invention. On top of GaP substrate 300A of a thickness 350A is grown an undoped GaP buffer layer 300B, to a thickness 350B of 1000 nm. This undoped GaP buffer. layer provides a high quality, single-crystal template for the subsequent growth of the overlying layers. On top of layer 300B is grown the first semiconductor layer 301, consisting of InAs doped n-type with silicon to a doping density of 1×10¹⁹ cm⁻³ and grown to a thickness 351 of 1000 nm using molecular beam epitaxy (MBE) with a substrate temperature of 500°C. LRER was used to optimize the materials quality of the InAs layer 301, forming a smooth, low defect-density surface despite the 11% lattice mismatch between the GaP and the InAs. On top of layer 301 is deposited a second semiconductor layer 302 consisting of undoped GaAs grown to an average thickness 352 of 20 nm and deposited at a substrate temperature of 500°C., forming the desired distribution of holes in the layer 302, at least some of which expose portions of the underlying layer 301, making it possible to deposit a third semiconductor layer inside the holes that make intimate contact between the nanostructured third semiconductor layer and the first semiconductor layer 301. On top of layer 302 is grown the third semiconductor layer 303 consisting of InAs doped n-type with silicon to a doping density of 1×10¹⁹ cm⁻³ and grown to a thickness 353 of 50 nm. This third semiconductor layer 303 at least partially fills some of the holes, forming the desired nanostructured material. The geometry of the nanostructured material is defined by the hole geometry, and the bottom contact to the nanostructured material can be made by contacting layer 301, which provides a very low resistance ohmic contact because layer 301 is highly conductive n-type InAs. The top contact to the nanostructure material is made by contacting layer 303. This embodiment of the invention makes use of the advantageous properties of the chosen semiconductors, including the 11% lattice mismatch between GaP and InAs and the 7% lattice mismatch between the GaAs and InAs layers, which provide. the strain mechanism for the formation of the holes in layer 302. Additionally, the n-InAs layers 301 and 303 readily make ohmic contact with most metals, because InAs surfaces are well known to pin the Fermi level inside the conduction band edge. The undoped GaAs layer 302 is relatively insulating, and provides about 0.7 eV of conduction band offset to the InAs layers, and therefore we expect to observe very little conduction between layers 301 and 303 for low bias, except for conduction through the nanostructured InAs in the holes.

Reference is now made to FIG. 3B, showing an AFM image of the top surface of a wafer grown in accordance with the layer structure and design of FIG. 3A. The X dimension of the scan 398 is 3 μm and the Y dimension of the scan 399 is 3 μm. As can be seen in the image, there is a plateau that rises less than 50 nm above the plane of the surface surrounding the hole 390. This is consistent with the AFM images from FIG. 2B, which show a build-up of material around each hole. This build-up occurs because the Ga and As atoms (from layer 302) and the In and As atoms (from layer 303) pile up near holes due to the relatively low diffusion coefficient of the atoms along the side wall of the hole. (This diffusion coefficient is temperature dependent, so deposition at higher temperatures promotes increased diffusion of InAs into the holes.) While is difficult from the AFM image alone to determine if the InAs inside the hole is thick enough to fill the hole, the thickness 353 of the InAs layer 303 is 2.5 times larger than the thickness 352 of the GaAs layer 302, which is sufficient to fill the hole 390. Ohmic contact to the nanostructured InAs inside hole 390 is made directly through a wide area deposition of a metal directly on top layer 303, which will contact directly inside the hole as well as the bulk region of layer 303 outside.

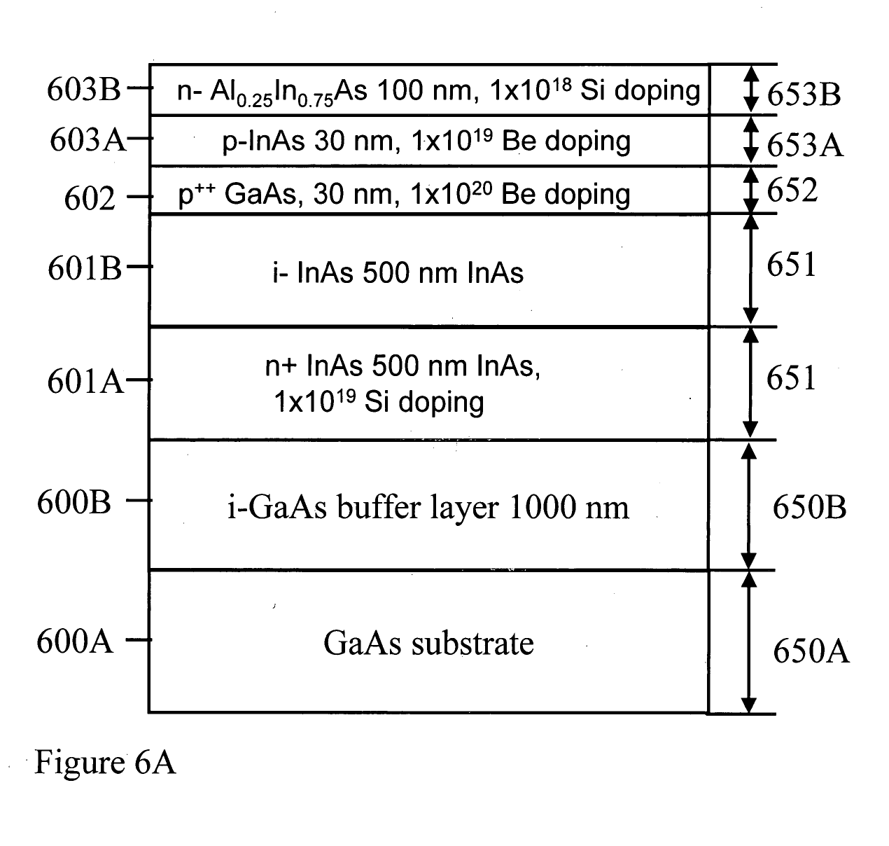

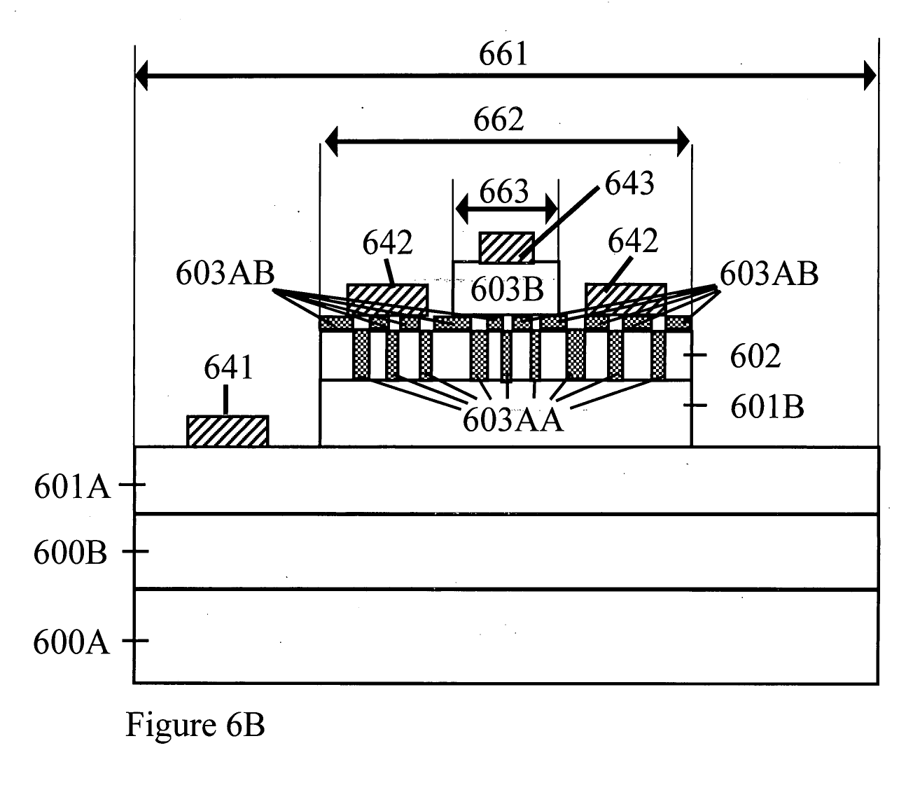

When the first and third semiconductor materials are the same, and the second semiconductor material differs, the nanostructure acts as a nanowire connecting the first and third layers. The process supports easy formation of good ohmic contacts to the nanowire, because contacts can be made to the first and third semiconductor layers with coarse (lateral) tolerances, and do not need to be made directly to the wire itself with tolerance to a deep sub-μm scale. Additionally, contact to the second semiconductor layer can be made, allowing a means for modulating the conductivity of the nanowire (see FIGS. 6A and 6B).

Reference is now made to FIG. 3C and FIG. 3D. FIG. 3C shows the cross section of the mesa structure of a test device fabricated from the wafer grown in accordance with the layer structure of FIG. 3A. FIG. 3D shows an over-head microscope image of the test device fabricated from the wafer grown in accordance with the layer structure of FIG. 3A. The fabrication proceeds by depositing a first contact 343 to layer 303, consisting of deposition of 10 nm of Ti, followed by deposition of 250 nm of Au. Contact 343 was defined as a dot contact with diameter 363A using standard photolithographic techniques. After contact 343 was defined, a circular first mesa 303A in layer 303 was defined using standard photolithographic and wet chemical etching techniques. We note here that certain enchants such as HF can be used to selectively remove the InAs layer 303 without etching the underlying GaAs layer 302. The diameter of this first mesa is 363B. Next, a second contact 342 to layer 302 was made by depositing 10 nm of Ti, followed by deposition of 250 nm of Au. Contact 342 was defined as a ring contact, with in inner diameter given by the sum of 363B and 362A, and an outer diameter given by the sum of 363B, 362A, and 362B. The definition of ring contact 342 was achieved using standard photolithographic techniques. The space between the inner diameter of the ring 342 and the first mesa 303A is 362A.

The space between the outer diameter of the ring 342 and the outer diameter of the circular mesa 302A is 362C. The circular mesa 302A was formed using standard photolithographic and wet-chemical etching techniques. Note that it is not necessary to use a selective etch to remove the portion of layer 302 outside of mesa 302A because the underlying layer 301 is sufficiently thick that a simple timed etch may be used to remove all of the layer 302 and a portion of layer 303 when forming mesa 302A. Following formation of mesa 302A, the contact 341 to the third semiconductor layer 301 was formed by depositing 10 nm of Ti and 250 nm of Au. The space between contact 341 and mesa 302A is 361A. The width of contact 341 is 361B. As shown in FIG. 3D, contact 341 is a long rectangular contact with width 361B.

Reference is now made to FIG. 3E, which shows the current voltage characteristics of a test device fabricated in accordance with FIGS. 3A-3D, where the diameter 363B of mesa 303A is 40 μm. Axis 388 is the voltage axis, with a linear voltage scale ranging from −1 V to +1 V. Axis 389 shows the current axis, with a linear current scale ranging from −1 mA to +1 mA. Curve 385 is the current-voltage characteristics of the device with mesa diameter 363B of 40 um. As expected, the curve shows rectifying characteristics, with a turn-on voltage near 0.7 V, which corresponds to the conduction band barrier height between InAs and GaAs.

Reference is now made to FIG. 3F, which shows the current voltage characteristics of a test device fabricated in accordance with FIGS. 3A-3D under low bias conditions. Axis 378 is the voltage axis, with a linear voltage scale ranging from −0.1 V to +0.1 V. Axis 379 shows the current axis, with a linear current scale ranging from −1 μA to +1 μA. Curve 373 is the current-voltage characteristics of a device with mesa diameter 363B of 14 μm. Curve 374 is the current-voltage characteristics of a device with mesa diameter 363B of 30 μm. Curve 375 is the current-voltage characteristics of a device with mesa diameter 363B of 50 μm. Here, none of the three curves indicates rectifying characteristics so the quantum barrier to current flow is low. The curves are approximately linear, which is consistent with current flowing predominately through the InAs nanowires, with low-resistance ohmic contacts. Since the density of nanowires here is approximately 10⁷ cm⁻², the 14 μm diameter device measured in curve 373 should contain about 15 nanowires, the 30 μm diameter device in curve 374 should contain about 70 nanowires, and the 50 μm diameter device in curve 375 should contain about 200 nanowires.

Reference is now made to FIG. 3G, which shows the current-versus-voltage characteristics of a test device fabricated in accordance with FIGS. 3A-3D. Axis 378B is the voltage axis, with a linear voltage scale ranging from −0.1 V to +0.1 V. Axis 379B shows the current density axis, with a linear current scale ranging from −0.05 A/cm² to +0.05 A/cm². Curve 373B is the current-voltage characteristics of a device with mesa diameter 363B of 14 um. Curve 374B is the current-voltage characteristics of a device with mesa diameter 363B of 30 um. Curve 375B shows the current-versus-voltage characteristics of a device with mesa diameter 363B of 50 um. Here, all three curves, which are now normalized with respect to mesa 363B area, lie on top of each other, indicating that the mechanism of current flow is uniform. This indicates that a substantial fraction of the holes in layer 302 must be deep enough to expose substantially the same fraction of contacting area between the nanowires and layer 301 despite the fact that the number of holes per device scales with area from about 15 nanowires for the smallest area device (curve 363B) to about 200 nanowires for the largest area device (curve 365B).

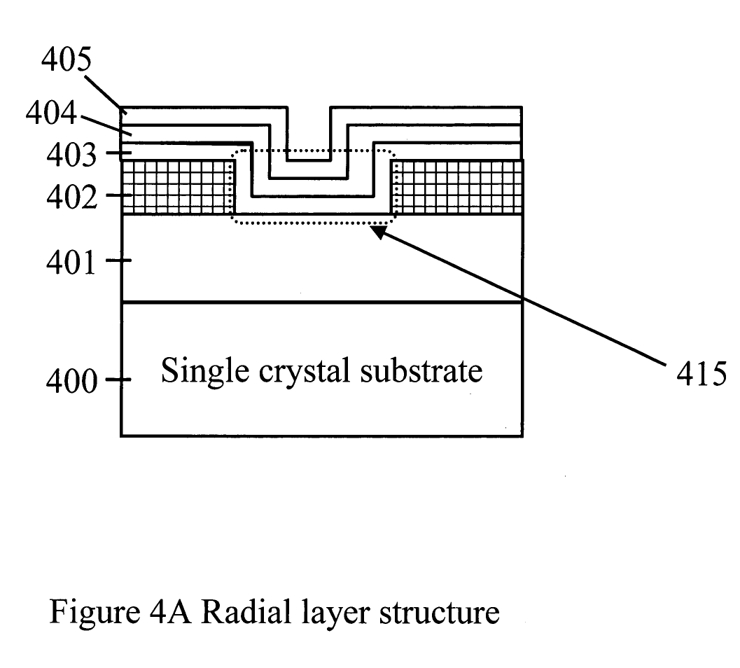

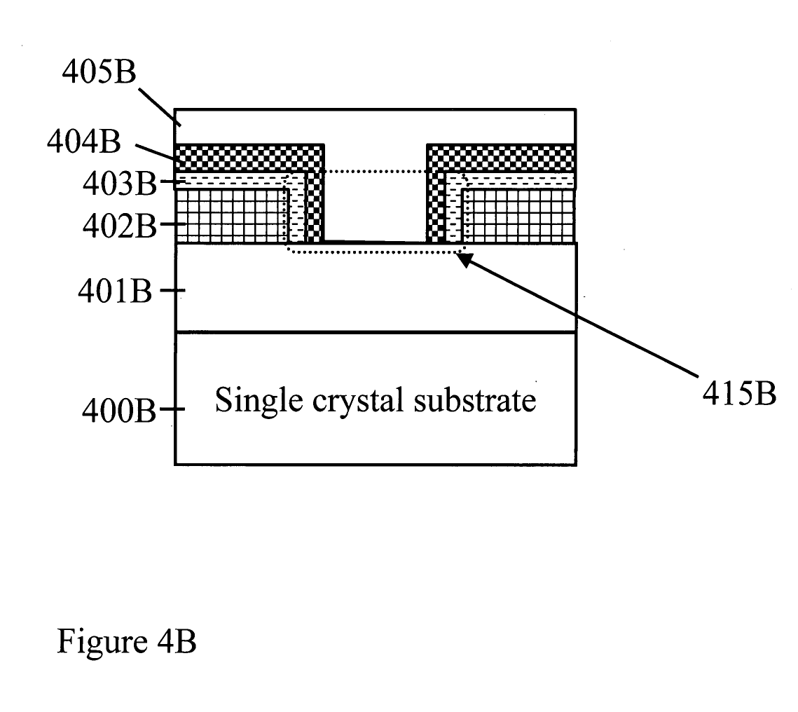

Reference is now made to FIG. 4A, showing an alternative embodiment where multiple layers are used to provide both a radial and vertical variation in the structure of the nanocylinder. On top of single crystal substrate 400 is grown a first semiconductor layer 401. In general, the lattice constant of layer 401 does not need to be matched to the lattice constant of substrate 400, so long as suitable pseudomorphic growth conditions are employed such that layer 401 exhibits a smooth surface. In some alternative embodiments, it may not be necessary to keep the surface smooth, provided that the overlying semiconductor layer 402 still exhibits suitable holes for the formation of nanostructures. On top of layer 401 is grown a second semiconductor layer 402. Growth conditions of layer 402 are chosen such that incomplete coverage is achieved, resulting in the formation of holes 415. The size, geometry, and density of the holes are dependent on growth conditions. After completion of the deposition of the second semiconductor layer 402, a third semiconductor layer 403 is grown using growth conditions optimized to fill all of the holes 415 as shown in the diagram. The third semiconductor layer 403 is kept thin enough that it does not, in general, completely fill in hole 415, but rather coats the sidewall and bottom of the hole 415 as shown in the figure. Similarly, a fourth semiconductor layer 404 and a fifth semiconductor layer 405 are deposited in sequence, gradually filling in the hole 415 and providing both a radial and vertical variation in the profile of the nanocylinder as shown in the figure. Those skilled in the art will recognize that additional layers can be inserted between the third semiconductor layer 403 and the forth semiconductor layer 404 to provide additional variation in the radial profile.

Reference is now made to FIG. 4B, showing an alternative embodiment where multiple layers are used to provide a predominately radial variation in the structure of the nanocylinder. On top of single crystal substrate 400B is grown a first semiconductor layer 401B. In general, the lattice constant of layer 401B does not need to be matched to the lattice constant of substrate 400B, so long as suitable pseudomorphic growth conditions are employed such that layer 401B exhibits a smooth surface. In some alternative embodiments, it may not be necessary to keep the surface smooth, provided that the overlying semiconductor layer 402B will exhibit suitable holes for the formation of nanostructures. On top of layer 401B is grown a second semiconductor layer 402B. Growth conditions of layer 402B are chosen such that incomplete coverage is achieved, resulting in the formation of holes 415B. The size, geometry, and density of the holes is dependent on growth conditions. After completion of the deposition of the second semiconductor layer 402B, a third semiconductor layer 403B is grown using growth conditions optimized such that selective growth is achieved, whereby the growth rate of layer 403B on layer 402B is substantially higher than the growth rate of layer 403B on layer 401B. By achieving selective growth, the desired radial variation in the composition can be achieved without also producing a vertical variation as shown in the figure. The third semiconductor layer 403B kept thin enough that it does not, in general, completely fill in hole 415B, but rather predominately coats the sidewall of the hole 415B as shown in the figure. Similarly, a fourth semiconductor layer 404B is selectively deposited to form an additional step in the compositional gradient of the radial profile. Finally, a fifth semiconductor layer 405B is deposited, which is used to completely fill in the hole 415B, completing the nanocylinder structure. Layer 405B does not require selective deposition, since it is used to completely fill in the core region of the nanocylinder as shown in the figure. Those skilled in the art will recognize that additional layers can be inserted between the third semiconductor layer 403B and the forth semiconductor layer 404B to provide additional variation in the radial profile.

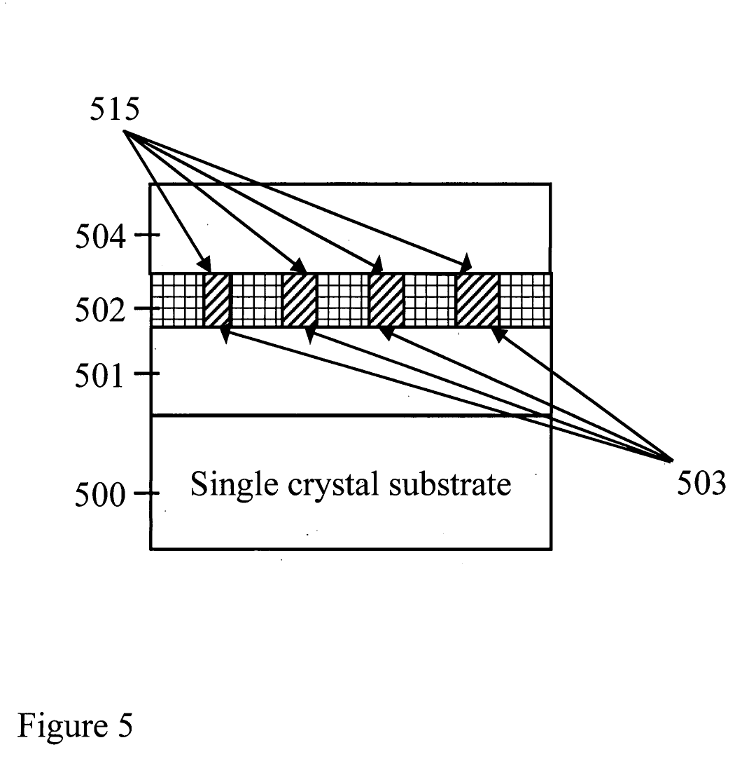

Reference is now made to FIG. 5, showing how nanodots can be created in accordance with the invention. On top of single crystal substrate 500 is grown a first semiconductor layer 501. In general, the lattice constant of layer 501 does not need to be matched to the lattice constant of substrate 500, provided suitable pseudomorphic growth conditions are employed such that layer 501 exhibits a smooth surface. In some alternative embodiments, it may not be necessary to keep the surface smooth, provided that the overlying semiconductor layer 502 exhibits suitable holes for the formation of nanostructures. On top of layer 501 is grown a second semiconductor layer 502. Growth conditions of layer 502 are chosen such that incomplete coverage is achieved, resulting in the formation of holes 515. The size, geometry, and density of the holes are dependent on growth conditions. After completion of the deposition of the second semiconductor layer 502, a third semiconductor layer 503 is grown using growth conditions optimized to fill all of the holes 515 as shown in the diagram. In this embodiment, it is desirable to confine the semiconductor layer 503 to the region of the holes 515, which may be achieved by either using selective growth, such that semiconductor layer 503 is preferentially grown on layer 501, or by using non-selective deposition of layer 503, followed by a polishing step that removes the excess layer 503 from on top of layer 502. Subsequently, a fourth semiconductor layer 504 is grown on top of layers 502 and 503 as shown in the figure. In this embodiment, nanodots of various geometries can be created, with their dimensions constrained by the size and geometry of holes 515.

Reference is now made to FIG. 6A showing the layer structure of nanowire heterojunction bipolar transistor (nano-HBT) in accordance with the invention. On top of GaAs substrate 600A of a thickness 650A is grown an undoped GaAs buffer layer 600B, to a thickness 650B of 1000 nm. This undoped GaAs buffer layer provides a high quality, single-crystal template for the subsequent growth of the overlying layers. On top of layer 600B is grown a sub-collector contacting layer 601A, consisting of InAs doped n-type with silicon to a doping density of 1×10¹⁹ cm⁻³ and grown to a thickness 651A of 500 nm using molecular beam epitaxy (MBE) with a substrate temperature of 500°C. LRER can be used to optimize the materials quality of the InAs layer 601A to form a smooth, low defect-density surface despite the 11% lattice mismatch between the GaP and the InAs. On top of sub-collector layer 601A is grown the collector layer 601B, consisting of undoped InAs grown to a thickness 651B of 500 nm using MBE with a substrate temperature of 500°C. On top of collector layer 601B is deposited the base contacting layer 602 consisting of p-type GaAs doped 1×10²⁰ cm⁻³ with Be using hyperdoping (see U.S. Pat. App. No. 2003/0121468) and grown to an average thickness 652 of 30 nm and deposited at a substrate temperature of 400°C. Layer 602 will form the desired distribution of holes in the layer 602, at least some of which expose portions of the underlying layer 601B, making it possible to deposit a nanowire base semiconductor inside the holes that make intimate contact between the nanowire and the collector layer 601B. On top of base contacting layer 602 is grown the nanowire base semiconductor layer 603A consisting of InAs doped p-type with Be to a doping density of 1×10¹⁹ cm⁻³ and grown to a thickness 653A of 30 nm. This nanowire base semiconductor layer 603A at least partially fills some of the holes, forming the desired plurality of nanowires. The geometry of the nanowires material is defined by the hole geometry, and contact to the nanowire base material can be made by contacting layer base contact layer 602, which provides a low resistance ohmic contact because layer base contact layer 602 is highly conductive p-type GaAs. Contact to base contact layer 602 is enhanced by the portion of layer 603A that lies outside the holes and on top of the base contact layer 602, because ohmic contacts to a narrow band gap semiconductor such as InAs is easier to achieve than ohmic contacts to GaAs. On top of the nanowire base layer 603A is grown the emitter layer 603B, consisting of Al_{0.25}In_{0.75}As doped n-type with Si to a doping density of 1×10¹⁸ cm⁻³ and grown to a thickness 653A of 100 nm.

Reference is now made to FIG. 6B. FIG. 6B shows the cross section of the mesa structure of nano-HBT device fabricated from the layer structure of FIG. 6A. The fabrication proceeds by depositing a first contact 643 on top of layer 603B. Contact 643 can be defined as a dot contact using standard photolithographic techniques. After contact 643 is defined, a circular first mesa in layer 603B is defined using standard photolithographic and wet chemical etching techniques. Selective enchanting is used to selectively remove the Al_{0.25}In_{0.75}As layer 603B without etching the underlying InAs layer 603A. The diameter of this first mesa is 663. Next, a second contact 642 to layer 602 is made, using a suitable metal in a ring shaped contact. The definition of ring contact 642 can be achieved using standard photolithographic techniques. Next, a second circular mesa defining the combination of layers 602 and 603A can be formed as shown in the diagram using standard photolithographic and wet-chemical etching techniques to remove layers 603A and 602 from the region outside the mesa. Note that it is not necessary to use a selective etch to remove only the portion of layer 602 outside of the mesa because the underlying layer 601B is sufficiently thick that a simple timed etch may be used to remove all of the layer 602 and a portion of layer 603. The diameter of this second mesa is 662. Following formation of second mesa, the contact to the third contact 641 is made using a suitable ring shaped metalization. The third contact 641 can be a ring contact surrounding the second mesa, as shown in cross section in the diagram. Finally, a third round mesa can be formed, as shown in the diagram with a mesa diameter of 661. Also shown in the diagram are the base nanowire regions 603AA, which are formed from the portion of layer 603A which are deposited inside the holes, and the regions 603AB, where are formed from the portion of layer 603A which are deposited on top of layer 602 outside of the hole regions. The regions 603AB facilitate ohmic contact between base contacting layer 602 and contact 642. The nano-HBT operates in analog to a conventional HBT, where the emitter contact is 643, the base contact is 642, and the collector contact is 641. In contrast to a conventional HBT, the active base region is confined to the nanowire regions 603AA, which are a very small portion of the total area of the device. By confining the active base region to nanowires 603AA, enhanced performance can be achieved. The nano size of 603AA accommodates the significant lattice mismatch between layers 603A and 603B, allowing more freedom in the choice of semiconductor materials. The nanowires 603AA can be made as perfect single crystals, with good surface passivation due to being surrounded by a high quality heterojunction interface to layer 602. Additionally, the heavy doping of the GaAs base contacting layer 602 will cause modulation doping of the InAs nanowires 603AA, with a significant fraction of the holes in the GaAs region being transferred to the nanowires. This provides an effective means of achieving low resistivity in the nanowire base regions, facilitating improved transistor performance. Those skilled in the art will recognize that the invention enables a wide range of semiconductor materials and thicknesses to be substituted in layers 600A, 600B, 601A, 601B, 602, 603A, and 603B as required to achieve the desired band gap, conductivity, lattice constant, and other properties of the semiconductors. Due to the nano-size of the active base regions nanowires 603AA, the strain of lattice mismatch is easily accomidated, which greatly frees up the design of the transistor. Alternative embodiments of the transistor can incorporate a homojunction for the emitter-base, and can use isotype heterojunctions to achieve a unipolar hot electron transistors ((see A F J Levi, T H Chiu, “Room-temperature operation of hot-electron transistors,” Appl. Phys. Lett. 51, 28 Sep. 1987, pp. 984 -986; T H Chi and A F J Levi, “Electron transport in an AlSb/InAs/GaSb tunnel emitter hot-electron transistor,” Appl. Phys. Lett. 55, 30 Oct. 1989, pp. 1891-1893; M Heiblum and M V Fischetti, “Ballistic hot-electron transistors,” IBM J. Res. Develop. 34(4), Jul. 1990, pp. 530 -549)).

The invention can also be used to create a field-effect transistor nanostructure by using the first semiconductor layer as the drain, the third semiconductor layer as the channel, the second semiconductor layer as the gate, and the fourth semiconductor layer as the source. In this case, contact to the gate region can be achieved by contacting the second semiconductor layer, which, in general will form a heterojunction with the third semiconductor layer. This heterojunction can be used to provide sufficient insulation between the gate and channel regions to enable the device to work as a field effect transistor. In a specific example, the first semiconductor material is an n⁺⁺InAs drain, the second semiconductor material is p⁻GaAs region with 200 nm holes, the third semiconductor material is n⁻InAs forming the nanostructured channel regions, and the forth semiconductor material can be an n⁺InAs source. The p⁻GaAs region could be used to provide the heterojunction to the n⁻InAs channel, with the bias on the p⁻GaAs region modulating the conductivity of the n⁻InAs channel. Fabricating this structure using a standard mesa isolation such as that shown in FIG. 6B would enable a high performance vertical InAs nanotransistor to be formed.

Additionally, those skilled in the art will recognize that the junctions between layers 1 and 3 can be used to form nanostructure diodes.

Nanostructure transistors or nanostructure diodes may be used to detect photons provided that one of the semiconductor layers is optically active such that the absorption of an irradiant photon generates a free electron-hole pair that can be separated by a junction or impose a bias on the gate or base region of a transistor.

Furthermore, notice is hereby given that the applicants intend to seek, and ultimately receive, claims to all aspects, features and applications of the current invention, both through the present application and through continuing applications, as permitted by 35 U.S.C. §120, etc. Accordingly, no inference should be drawn that applicants have surrendered, or intend to surrender, any potentially patentable subject matter disclosed in this application, but not presently claimed. In this regard, potential infringers should specifically understand that applicants may have one or more additional applications pending, that such additional applications may contain similar, different, narrower or broader claims, and that one or more of such additional applications may be designated as not-for-publication prior to grant.

We claim:

1. A means of forming a nanostructure entailing the steps of
(a) forming a second semiconductor material on top of a first semiconductor material under semiconductor growth conditions that provide incomplete coverage of said second material on the surface of the first semiconductor layer, said incomplete coverage including a multiplicity of holes in said second semiconductor material, and
(b) depositing a third semiconductor material that at least partially fills said holes to form a multiplicity of nanostructures.

2. The method of claim 1 wherein said first semiconductor material comprises a compound of Ga, Al, and/or In with N, As, P, and/or Sb.

3. The method of claim 1 wherein said second semiconductor material comprises a compound of Ga, Al, and/or In with N, As, P, and/or Sb.

4. The method of claim 1 wherein said third semiconductor material comprises a compound of Ga, Al, and/or In with N, As, P, and/or Sb.

5. The method of claim 1 wherein said first and third semiconductor materials each contain In and As.

6. The method of claim 1 wherein at least one of said first, second, or third semiconductor materials includes Si, Ge, and/or C.

7. The method of claim 1 where the density of holes is greater than 10⁶ cm⁻².

8. The method of claim 7 where the density of holes is greater than 10⁷ cm⁻².

9. The method of claim 8 where the density of holes is greater than 10⁸ cm⁻².

10. The method of claim 9 where the density of holes is greater than 10⁹ cm⁻².

11. A field-effect transistor whose drain is located in a first layer of a first semiconductor material, gate is located in a second layer of a second semiconductor material, source is located in a third layer of a third semiconductor material, and channel region comprises a plurality of nanostructures of said third semiconductor material embedded in said second semiconductor material.

12. The transistor of claim 11 further including a fourth layer of a fourth semiconductor material, and a source contact located in said fourth semiconductor material.

13. The transistor of claim 12 wherein said first and fourth semiconductor materials are n-type and said second semiconductor material is p-type.

14. The transistor of claim 12 wherein said first and fourth semiconductor materials are p-type and said second semiconductor material is n-type.

15. The transistor of claim 12 further including at least one further semiconductor material located between said third and said fourth semiconductor materials.

16. The transistor of claim 11 such that the concentrations of the elements comprising said first semiconductor material are each within 10% of the concentrations of the elements comprising said third semiconductor material.

17. A transistor defined in claims 11-15 except swapping the drain and source.

18. A bipolar junction transistor whose collector is located in a first semiconductor material, base contact is located in a second semiconductor material, emitter is located in a third semiconductor material, and active base region comprises a plurality of nanostructures of said third semiconductor material embedded in said second semiconductor material.

19. The transistor of claim 18 further including a fourth semiconductor material, and an emitter contact located in said fourth semiconductor material.

20. The transistor of claim 19 wherein said first and fourth semiconductor materials are n-type and said third semiconductor material is p-type.

21. The transistor of claim 19 wherein said first and fourth semiconductor materials are p-type and said third semiconductor material is n-type.

22. The transistor of claim 19 further including at least one further semiconductor material located between said third and said fourth semiconductor materials.

23. The transistor of claim 18 such that the concentrations of the elements comprising said first semiconductor material are each within 10% of the concentrations of the elements comprising said third semiconductor material.

24. A transistor defined in claims 18-23 except swapping the emitter and collector.

25. A unipolar junction transistor whose collector is located in a first semiconductor material, base contact is located in a second semiconductor material, emitter is located in a third semiconductor material, and active base region comprises a plurality of nanostructures of said third semiconductor material embedded in said second semiconductor material.

26. The transistor of claim 25 further including a fourth semiconductor material, and an emitter contact located in said fourth semiconductor material.

27. The transistor of claim 26 wherein said first, second, third and fourth semiconductor materials are each n-type or i-type.

28. The transistor of claim 26 wherein said first, second, third, and fourth semiconductor materials are each p-type or i-type.

29. The transistor of claim 26 further including at least one further semiconductor material located between said third and said fourth semiconductor materials.

30. The transistor of claim 26 such that the concentrations of the elements comprising said first semiconductor material are each within 10% of the concentrations of the elements comprising said third semiconductor material.

31. A transistor defined by claims 25-30 except swapping the emitter and collector.

32. A PN junction whose p-type region is located in a first semiconductor material and n-type region is located in a third semiconductor material embedded in a second semiconductor material, said n-type region penetrating into a plurality of holes in said second semiconductor material, said holes exposing said p-type region.
